(19) United States
(12) Patent Application Publication
(10) Pub. No.: US 2003/0133412 A1
(43) Pub. Date: Jul. 17, 2003

(54) VLAN to MPLS mapping: method to establish end-to-end traffic path spanning enterprise local area networks and a global network

(76) Inventors: Arvind B. Iyer, San Jose, CA (US); Ashutosh Singla, Folsom, CA (US)

Correspondence Address: Pillsbury Winthrop LLP, Intellectual Property Group, 1600 Tysons Blvd., McLean, VA, 22102, US

(21) Appl. No.: 10/044,325

(22) Filed: Jan. 10, 2002

(51) Int. Cl. G01R 31/08; H04L 12/56

(52) U.S. Cl. 370/235; 370/401

(57) ABSTRACT

A virtual end-to-end circuit is established spanning at least two enterprise local area networks (LAN) and a global network. A first virtual local area network identifier (VLAN-ID) is established to transport packets from a source endsystem in the first enterprise LAN to an ingress routing device on the global network. The ingress routing device is included in the VLAN-ID tables. In the global network, a label-switched path is created through a plurality of routers to transport the packets sent by the source endsystem to an egress routing device of the global network. A second VLAN-ID is established to transport packets from the egress routing device on the global network to a destination endsystem on the second enterprise LAN and complete the virtual end-to-end circuit.

### BACKGROUND OF THE INVENTION

1. Field of the Invention

The present invention generally relates to communication in enterprise local area networks (LAN) and a global network. More particularly, the present invention relates to establishing an end-to-end virtual circuit that is secure and fast between a source enterprise local area network, a global network, such as the Internet, and a destination enterprise LAN.

2. Discussion of the Related Art

Data communication networks rely heavily on shared, packet-based technologies for both access and backbone connections. Global networks, e.g., the Internet, comprised of routers, hubs, and switches allow the connection of multiple LANs in a global environment. The Internet routers or other similar devices are capable of processing packets having different protocols.

As the Internet has grown in popularity, many bandwidth intensive applications are utilizing the Internet as a communication medium. Applications like videoconferencing and Internet Protocol (IP) telephony require large amounts of bandwidth in order to perform at the level required by their customers. The performance aspect of both videoconferencing and IP telephony require not only large amounts of bandwidth but also guaranteed bandwidth. In addition, these applications require security because users do not desire to have unwanted parties eavesdropping on conversations or conferences. The data utilized by videoconferencing and IP telephony applications needs to be available only to the users participating in the service and must be passed from the source to the destination as quickly as possible to enable users to be satisfied with the service.

The need for speed and security must be addressed in both the global network and the local area networks where the source and destination endsystems are located. When the data packets are travelling in the enterprise networks containing the source and destination endsystems, virtual local area networks (VLANs) have provided both speed and security for the data packets.

VLANs are the grouping of devices and endsystems on different physical LAN segments that can communicate with each other as if they were all on the same physical LAN segment. FIG. 1 illustrates a VLAN established in an enterprise local area network according to the prior art. End systems 02, 04, 10, 16 are all part of VLAN 20 even though they reside on different physical LAN segments.

VLANs are implemented through switches on the enterprise network. The creation of VLANs allows the endsystems and devices on the VLAN to be grouped into a broadcast domain, and the performance in the network is increased because broadcast traffic is limited to users performing similar functions or within similar workgroups.

IP telephony and videoconferencing have driven the demand for increased and guaranteed bandwidth in the backbone of the network. The popularity of the Internet has required the Layer 3 (Network Layer) switching devices to handle Layer 3 routing in high-speed switching hardware in order to keep pace with speed demands. Currently, the routing of packets on the Internet is based on routing protocols utilizing algorithms to obtain the shortest path in the Internet, and not taking into account such factors as delay or congestion.

Multiprotocol label switching (MPLS) is designed to be a versatile solution and to assist in the speed and security problems the Internet is facing. In MPLS, the transmission of data packets occurs over label-switched paths (LSPs). A sequence of labels is established from the source of the transmission to the destination at each and every node, e.g., router, along the path. The labels may be established based upon detection of a certain flow of data and may be distributed using a label distribution protocol (LDP) or piggybacking on existing routing protocols. Each data packet encapsulates and carries the labels from the ingress router to the egress router.

Multiprotocol label switching (MPLS) provides a virtual path capability between between routers to efficiently carry differentiated services across the Internet. High-speed switching is possible over the Internet if the routers are MPLS-enabled because the fixed-length labels are inserted at the very beginning of the packet or cell and are used by the routing hardware to switch the packet quickly between links. A transmission on a LSP is secure because only devices on the LSP interact and transfer the data.

Currently, however, the advantages of secure and fast connections are housed separately in the Internet and within the enterprise LANs. There is no feasible way to allow transmission from a source endsystem to a destination endsystem spanning a global network and multiple enterprise LANs. Accordingly, a need exists for a method and system to allow fast and secure communications for newly developed applications, such as IP telephony and videoconferencing.

### BRIEF DESCRIPTION OF THE DRAWINGS

FIG. 1 illustrates a virtual local area network established in an enterprise local area network according to the prior art;

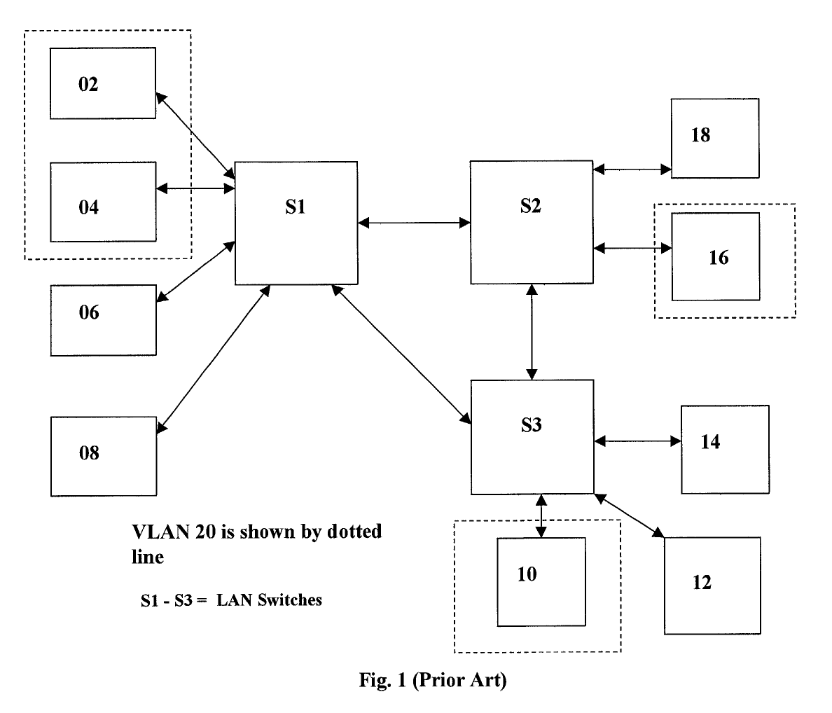

FIG. 2(a) illustrates an end-to-end virtual circuit spanning enterprise local area networks and a global network according to an embodiment of the present invention;

FIG. 2(b) illustrates a virtual local area network in an end-to-end virtual circuit spanning enterprise local area networks and a global network according to an embodiment of the present invention;

FIG. 3 illustrates a local area network switch and associated ports according to an embodiment of the present invention;

FIG. 4 illustrates a network of multiprotocol label switched (MPLS)-enabled routers in a global network according to an embodiment of the present invention;

FIG. 5 illustrates a label-switched path on a global network according to an embodiment of the present invention;

FIG. 6 illustrates a plurality of routers including a label-switched path and the corresponding label information base tables for the label-switched path according to an embodiment of the present invention;

FIG. 7 illustrates transmission of a packet through an enterprise local area network including a plurality of switches by utilizing one virtual local area network (VLAN) and also by utilizing two VLANs according to an embodiment of the present invention;

FIG. 8 illustrates a virtual circuit with multiple enterprise local area networks connected by multiple routing segments according to an embodiment of the present invention; and

FIG. 9 illustrates an intermediate enterprise local area network's transmission of data packets from a preceding routing segment to a succeeding routing segment according to an embodiment of the invention.

### DETAILED DESCRIPTION OF THE INVENTION

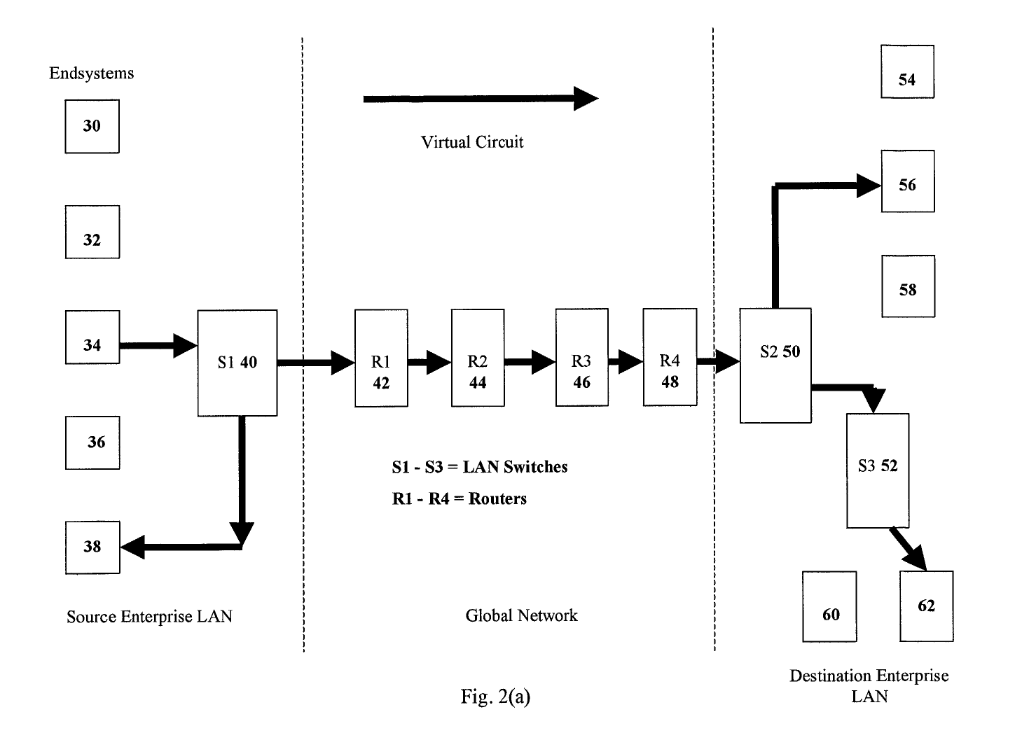

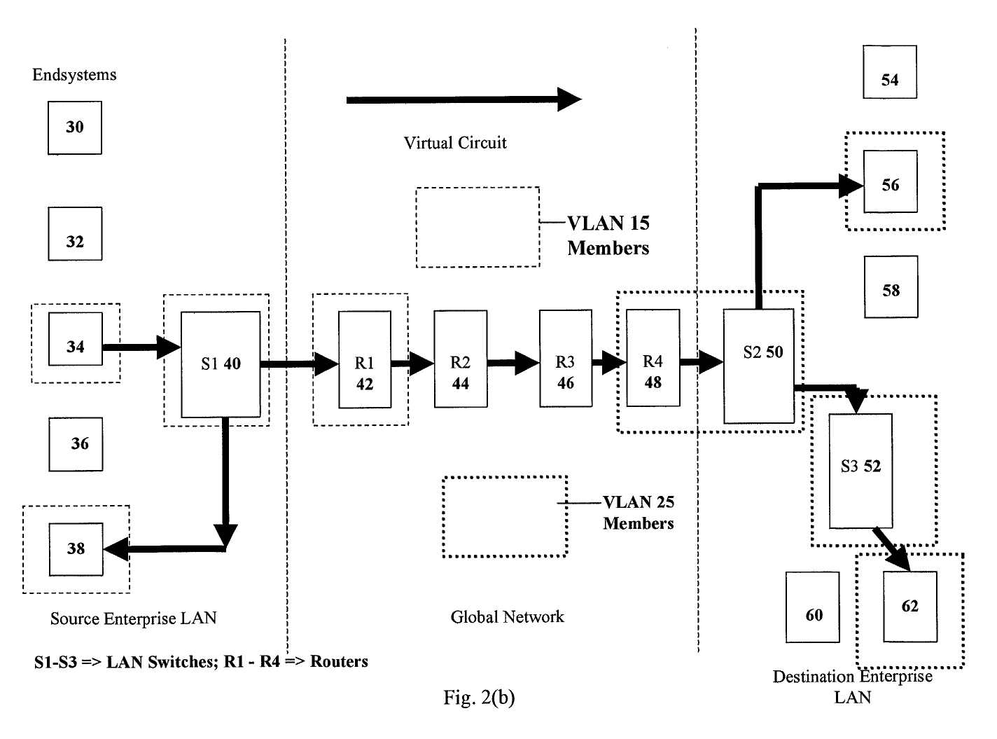

FIG. 2(a) illustrates an end-to-end virtual circuit spanning at least two enterprise local area networks (LANs) and a global network according to an embodiment of the present invention. The present invention establishes a fast and secure end-to-end virtual circuit from a source enterprise LAN to a destination enterprise LAN via a global network by mapping a multiprotocol labeling system (MPLS) tag to a virtual local area network identifier (VLAN-ID) and vice-versa. In other words, the MPLS-enabled routers and the corresponding label-switched path (LSP) are connected to the VLANs in each enterprise network to form the end-to-end virtual circuit (EEVC). The EEVC is established in one direction from source to destination. The same principles apply when a transmission is made in the opposite direction, e.g., original destination to original source, rather than source to destination, as is necessary in two-way communication applications like videoconferencing and IP telephony.

FIG. 2(a) illustrates a representative end-to-end virtual circuit (in bold arrows) that spans a source enterprise LAN, a global network, and a destination enterprise LAN according to an embodiment of the present invention. The source enterprise LAN includes a plurality of endsystems 30, 32, 36, and 38 including a source endsystem 34 and a LAN switch S1 40. The global network includes a plurality of MPLS-enabled routers R1 42, R2 44, R3 46, and R4 48. The destination enterprise LAN includes a LAN switch S2 50, a LAN switch S3 52, a plurality of destination endsystems 54 58 including a destination endsystem 56 connected to the LAN switch S2 50, and a plurality of destination endsystems 60 62 connected to the LAN switch S3 52. The end-to-end virtual circuit (EEVC) includes only devices that are running the application for which the virtual circuit has been established. For example, if the application of the virtual circuit is a videoconference among endsystems 34, 38, 56 and 62, then endsystems 34 and 38, LAN switch S1 40, routers R1 to R4 42 44 46 48, LAN switch S2 50, endsystem 56, LAN switch S3 52, and endsystem 62 form the EEVC for this particular application.

The first/source enterprise LAN includes the source endsystem 34, the plurality of additional endsystems 30 32 36 38, and the LAN switch S1 40. A network administrator establishes a VLAN on the source enterprise LAN by inputting information into a LAN switch's VLAN-ID table. The protocol for establishing the VLAN-ID may be a general attributes registration protocol (GARP) VLAN registration protocol, otherwise known as GVRP. Alternatively, a software program may establish the VLAN-ID by inputting the information automatically. The information includes what endsystems are included in each specific VLAN (endsystem information), and also includes the port designation used to communicate with each endsystem, switch, or device that is part of the VLAN (port designation information). In another embodiment of the invention, the endsystem information and port designation information each are contained in separate VLAN tables.

According to an embodiment of the present invention, a first leg of the virtual circuit is completed by including a local edge router (LER) on the VLAN in the source enterprise LAN. Alternatively, the LER may also be referred to as an ingress router. The local edge router is a router that is located at the edge of the global network and directly communicates with a switch on an enterprise LAN. In other words, the network administrator or software program maps the VLAN-ID to the LER and includes the port that connects the switch to the LER in its VLAN port designation information. Because the LER is included in the VLAN, the LER may receive packets from the LAN switch because the LAN switch automatically transfers packets from any device on the VLAN to all of the other devices on the VLAN.

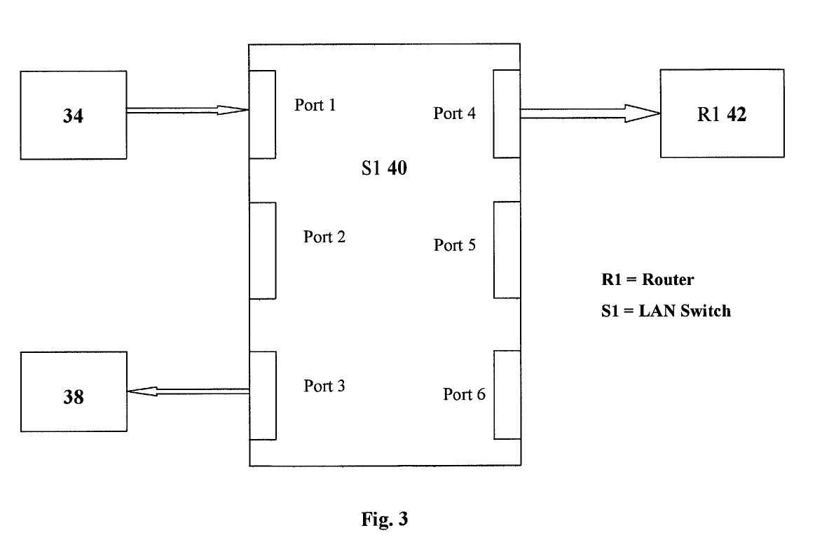

For example, as illustrated in FIG. 2(b), the network administrator or software program may construct a VLAN-ID table in LAN Switch S1 40 for VLAN 15. VLAN 15 includes endsystem 34, endsystem 38, LAN switch S1 40, and router R1 42 (the LER or ingress router). FIG. 3 illustrates a LAN switch and associated ports according to an embodiment of the present invention. Endsystem 34 is connected to port 1 on LAN switch S1 40; endsystem 38 is connected to port 3 on LAN switch S1 40; and router R1 42 is connected to port 4 on LAN switch S1 40. The VLAN table may include two sections of information: first, a mapping of VLAN-IDs to endsystems; and second, a mapping of the ports designated for each VLAN-ID. Illustrative tables for the embodiment discussed above are set forth below.

VLAN Endsystem Table for LAN Switch S1 40

| Access Port | Devices Heard | VLAN-1D |
|---|---|---|
| 1 | 34 | 15 |
| 3 | 38 | 15 |
| 4 | 42 | 15 |

VLAN-Port Designation Table for LAN Switch S1 40

| VLAN-ID | ACCESS PORT |
|---|---|
| VLAN 15 | 1 |
| VLAN 15 | 3 |
| VLAN 15 | 4 |

When the LAN switch S1 40 receives a packet from endsystem 34 (the source endsystem), it retrieves from the endsystem table that VLAN-ID 15 is associated with endsystem 34. S1 40 encapsulates the original packet with a VLAN header that contains a list of the VLAN-IDs with which the source endsystem 34 is associated with. In this example, the packet has a VLAN header indicating that it is to be transmitted to other devices on VLAN 15. LAN Switch S1 40 also determines which ports are associated with VLAN 15 by accessing the VLAN-port designation table. After determining which ports are associated with VLAN 15, LAN Switch S1 40 transmits the packet out of all the associated access ports except for the source port (in this case, port 1). Illustratively, the packet is sent out of access port 3 to endsystem 38 and out of access port 4 to router R1 42.

The packet is being transmitted to the edge of the global network quickly because the LAN switch S1 40 needs only to access the VLAN tables before transferring the packet. In addition, the packet is transmitted securely because only the members of the VLAN (for example, teleconference members) receive the packet. In other words, the VLAN of the source enterprise LAN is now extended (or mapped) to the Local Edge Router R1 42. Each successive packet follows the path of the first packet.

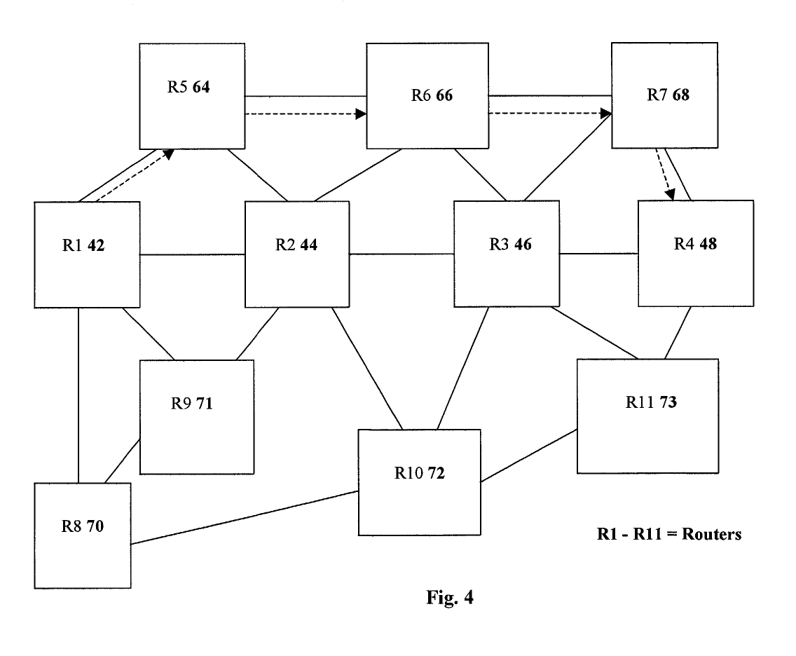

The next leg on the end-to-end virtual circuit (EEVC) is through the global network, such as the Internet. FIG. 4 illustrates a group of MPLS-enabled routers in a global network according to an embodiment of the present invention. A network that is MPLS-enabled is referred to as an MPLS domain. Illustratively, the global network includes routers R1 42, R2 44, R3 46, R4 48, R5 64, R6 66, R7 68, R8 70, R9 71, R10 72, and R11 73. Using MPLS, the packets enter the global network at Router R1 42 and exit the global network at Router R4 48. R1 42 may be referred to as an ingress router; R4 48 may be referred to as an egress router. Also, both R1 42 and R4 48 may be referred to as Local Edge Routers (LER) because the two routers are on the edges of the global network. On the global network, a packet may travel on many different paths from R1 to R4. For example in FIG. 4, the packet(s) may travel from R1 42 to R5 64 to R6 66 to R7 68 to R4 48, or via any of a number of alternative routes.

When utilizing MPLS, the routing of the first packet determines the routing of successive packets and establishes the MPLS leg of the end-to-end virtual circuit or the virtual circuit in the global network. All packets with the same characteristics as the first packet travel through the global network utilizing the same MPLS virtual circuit established by the first packet.

When the packet first enters the global network at R1 42, the packet may be provided with an equivalence class. The assigning of an equivalence class allows each packet in a group to share the same transport requirements. In an embodiment of the invention, all packets transferred to the router R1 42 via a specific port indicate the packets are being transferred on a VLAN and belong to one equivalence class.

In a MPLS domain, a path, commonly referred to as a label-switched path (LSP), is established for given packets to travel based on the equivalence class. The path of the first packet may establish the path for all of the packets with the same characteristics. The LSP may be established by “hop-by-hop” routing, where each router successively selects the next hop for the packets based upon a variety of factors. The routers may use any available routing protocols such as open shortest path first (OSPF), border gateway protocol (BGP), or asynchronous transfer mode (ATM) private network to network interface (PNNI) to establish the LSP. Alternatively, the LSP may be established by explicit routing where the ingress router, e.g., R1 42, specifies the list of nodes/routers through which the packet are to travel.

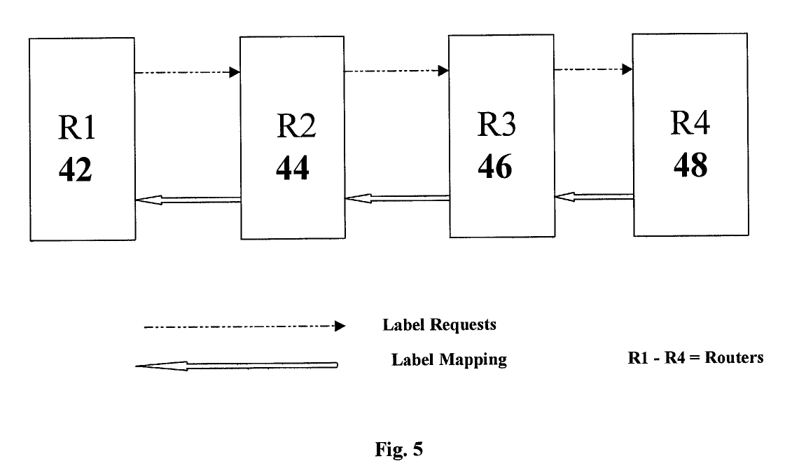

FIG. 5 illustrates the creation of a label-switched path (LSP) on the global network according to an embodiment of the present invention. If “hop-by-hop” routing is used and R2 44 is chosen as the next router, then R1 42 initiates a label request through R2 44. The request continues through the network to the egress router, e.g., from R2 44 to R3 46 to R4 48. Each intermediary router may receive a MPLS label from its downstream router: R3 46 receives a MPLS label from R4 48 and R1 42 receives a MPLS label from R2 44. The LSP is established by the distribution of the MPLS labels. A label distribution protocol (LDP) or any other signaling protocol may be used in establishing the LSP.

When a router receives a label from the downstream router, the router establishes a table, e.g., a label information base (LIB). The following table illustrates an example LIB table for a packet stream. The LIB table ties together the input port, the incoming MPLS label, the output port and the outgoing port label.

| Input Port | Incoming Port Label | Output Port | Outgoing Port Label |
|---|---|---|---|
| 1 | 3 | 4 | 8 |

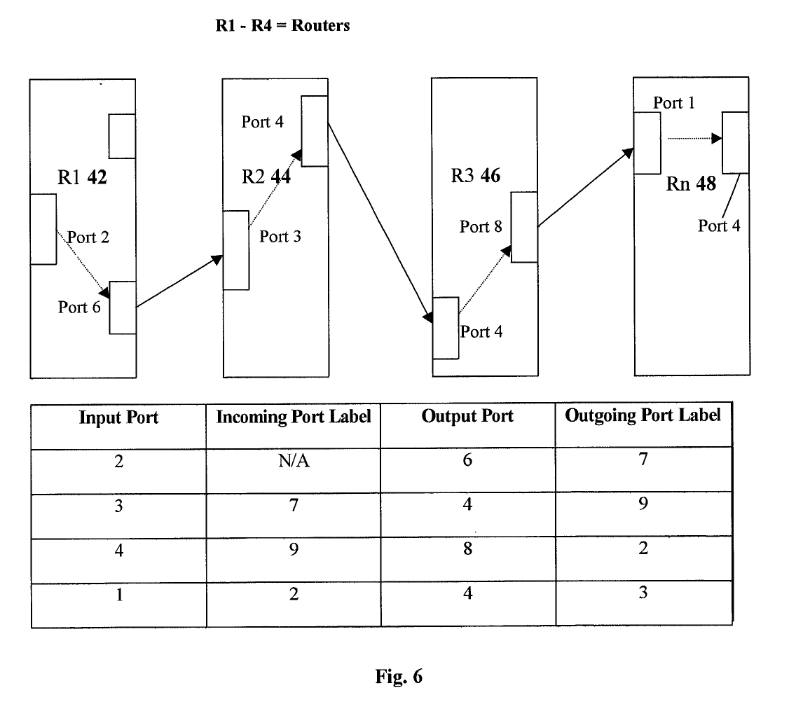

FIG. 6 illustrates a plurality of routers including a label-switched path and corresponding label information base (LIB) tables for the label-switched path according to an embodiment of the present invention. For example, the initial router R1 42 may insert the MPLS label into the first packet and forward the packet to R2 44. Each subsequent router examines the port label of the received packet and replaces it with the outgoing label and forwards it to the next router. For example, R3 46 receives the packet from R2 44, examines the label of the received packet, e.g., 9, replaces the label with the outgoing port label, e.g., 2, and sends the packet out port 8. When the packet reaches the last router in the global network, the last router may remove the label packet because it is exiting the MPLS domain and the label packet is no longer needed. The subsequent packets sent by the VLAN of the first enterprise network follow the same MPLS LSP in the global network as that of the first packet.

When the packets reach the last router of the global network, e.g., the egress router, the egress router identifies to which LAN switch the packet(s) are to be sent. The router determines which LAN switch is the destination of the packet by comparing the packet's IP destination address prefix to a routing table. The egress router then maps the IP address to a physical address. For example, a router may contain entries in a routing table similar to the following:

12.129.xx.xx=Direct Delivery→Means these addresses are connected to the network and the packets need to be delivered to a LAN switch to forward to these addresses.

23.32.xx.xx=Forward to Router 13→Not directly on network.

27.52.xx.xx=Forward to Router 14→Not directly on network.

If a packet arrives with an IP destination address of, for example, 12.129.2.3, then the egress router utilizes its routing table and determines if the address is somewhere on this physical network. If the router then finds the physical address through another lookup, or by using a protocol name address resolution protocol, the router sends it out over the physical enterprise LAN to the appropriate switch.

The last leg of the virtual circuit is completed by the establishment of a VLAN on the second or destination enterprise LAN. A network administrator, or software program, establishes the VLAN to include devices participating in the same application as the devices in the source enterprise LAN. The egress routing device on the global network is included in the destination enterprise LAN's VLAN to allow fast and secure travel through the destination enterprise network to the endsystems that are participating in the application.

As illustrated in FIG. 2(b), the second, or destination, enterprise LAN includes endsystems 54 58 60 62, destination endsystem 56, LAN switch S2 50, and LAN switch S3 52. Endsystems 54, 56, and 58 are connected to LAN switch S2 50. Endsystems 60 and 62 are connected to LAN switch S3 52. In one embodiment of the invention, VLAN 25 includes router R4 48, endsystem 56, endsystem 62, LAN switch S2 50 and LAN switch S3 52. In one embodiment of the invention, a network administrator constructs a VLAN-ID table in LAN switch S2 50 for VLAN 25. Alternatively, a software program constructs a VLAN-ID table in LAN switch S2 50 for VLAN 25. Note that since the enterprise networks are separate and distinct from each other, a new network administrator or software program is used to establish the VLAN.

When the LAN switch S2 50 receives a packet from router R4 48, it retrieves from its VLAN endsystem table that VLAN-ID 25 is associated with router R4 48. LAN switch S2 50 encapsulates the packet with a VLAN header indicating the packet is to be transmitted to members of VLAN 25. LAN switch S2 50 also determines which ports are associated with VLAN 25 by accessing the VLAN port designation table. After determining which ports are associated with VLAN 25, S2 50 transmits packets out of all the associated ports except for the port connected to R4 48. The transmission includes sending the packet(s) to LAN switch S3 52 and endsystem 56. Even though endsystem 62 is also on VLAN 25, it is not directly connected to LAN switch S2 50 and is not entered into the S2's VLAN endsystem table.

When LAN switch S3 52 receives the packet with the VLAN 25 header, LAN switch S3 52 accesses its VLAN endsystem table to determine which endsystems are associated with VLAN-ID 25 and accesses the VLAN port designation table to determine with which ports the VLAN is associated. In one embodiment of the invention, LAN switch S3 52 sends out the transmission on all of the ports associated with VLAN-ID 25 except for the incoming port. In one embodiment of the invention, LAN switch S3 52 sends out the transmission to endsystem 62 since it is the only endsystem associated with VLAN-ID 25 connected to LAN switch S3 52.

Alternatively, LAN switch S3's 52 VLAN endsystem table may identify that all communications received from the specific port that is attached to LAN switch S2 are members of a separate VLAN, e.g., VLAN 35. In this example, LAN switch S3 52 investigates its VLAN endsystem table to determine which endsystems are associated with VLAN 35 and checks its VLAN port designation table to determine which ports may receive the transmission. Therefore, if endsystem 56 is a member of VLAN 35, endsystem 56 receives the transmission.

In applications such as videoconferencing over the Internet and IP telephony, communication flows in both directions between parties. Therefore, an end-to-end virtual circuit needs to be established from the original destination enterprise LAN back to the original source enterprise LAN. The virtual circuit segments, e.g., the VLANs, in both the original destination and the original source enterprise LANs may be utilized in directing a communication from the new source (old destination) enterprise LAN over the global network to the new destination (old source) enterprise LAN. Alternatively, new VLANs may be established in the new source and new destination enterprise LANs to transmit the packets.

In one embodiment of the present invention, the communication may originate from endsystem 56, which has now become the source endsystem for these communications. LAN switch S2 50 receives the communication, understands the packet should be transmitted on VLAN-ID 25, and sends it out to all ports associated with VLAN-25. This VLAN-ID includes the port connected to R4 48. The same VLAN-ID may be utilized for both directions of the communication because the same application is directing the communication. Illustratively, the edge router on the global network, e.g., R4 48, receives the packet or packets and begins the process of establishing the virtual circuit through the global network back to a destination endsystem on the first enterprise LAN (the original source enterprise LAN.)

MPLS establishes only a one-way virtual circuit so a separate label-switched path (LSP) is established for communications flowing in the opposite direction. The edge router, e.g., R4 48, receives a packet from a LAN switch because the edge router is included in the VLAN-ID, e.g., VLAN 25. The VLAN-ID means all packets are treated in the same manner.

As discussed previously, router R4 48 may determine the next hop in the network via a variety of methods. When the next hop is determined, the new ingress (old egress) router requests a label from the next router. This process continues until the path reaches the new egress router (old ingress router). The new egress router then passes a label to the router that requested the label from it. This process continues back to the new ingress router and forms the label-switched path (LSP). The LSP created for communication between the new ingress router and the new egress router does not have to utilize the same routers that the LSP between the old ingress router and the old egress router utilized. In other words, the routers utilized in the LSP for the traffic flowing from R4 48 to R1 42 do not have to be the same routers utilized in the LSP for the traffic flowing from R1 42 to R4 48.

FIG. 4 illustrates a network of MPLS-enabled routers according to an embodiment of the present invention. In one embodiment of the invention, a LSP is created for packet traffic between R4 and R1. In one embodiment of the invention, the label switched path includes R4 48, R3 46, R2 44 and R1 42. In another embodiment of the invention, the label switched path includes R4 48, R6 66, R5 64, and R1 42. In the embodiment where R4 48 is the new ingress router and R1 42 is the new egress router, R4 48 places a label on the packet to instruct the router how to transmit the packet. R4 48 accesses its LIB table to determine where the packet is to be transmitted and which port is to be utilized. R3 46 examines the label from router R4 48, utilizes its LIB table to determine where the packet is to be sent, discards router R4's 48 label and inserts its outgoing label on the packet. The process of investigating the incoming label and replacing the outgoing label continues until the packet reaches the new egress router, e.g., R1 42.

The routing table in the new egress router R1 42 then investigates the packet's destination IP address to determine if the address is located on a network connected to the router, as discussed previously. If the new address is located on the enterprise network connected to the new egress router R1 42, the new egress router forwards the packet to the enterprise network. In one embodiment of the invention, R1 42 investigates the packet's destination IP address and determines that the destination IP address is located on the enterprise LAN connected to R1 42 by LAN switch S1 40 and transmits the packet to S1 40.

In one embodiment of the present invention, the LAN switch S1 40 receives the incoming packet from router R1 42 and identifies that the packet is associated with VLAN-ID 15 because the packets were received on a port that is a member of VLAN-ID 15, e.g., port 4 in S1 40 connected to R1 42. S1 40 investigates its VLAN endsystem table to establish that endsystem 34, endsystem 38 and router R1 42 are members of VLAN 15. S1 40 investigates its VLAN-access port table to determine which ports should be utilized to transmit to the members of VLAN-ID 15. After accessing the VLAN port designation table, S1 40 transmits the packets to both endsystem 34 and endsystem 38 on ports 1 and 3, respectively.

In an alternative embodiment of the invention, an enterprise LAN may include a plurality of switches. The packets transmitted in the enterprise LANs may travel through all of the switches contained in the intermediate enterprise LAN according to VLAN techniques discussed previously. Alternatively, the packets may only travel through two or three of the LAN switches included in the enterprise network. In addition, the plurality of switches may all utilize one VLAN for the transmission of packets or the plurality of switches may utilize multiple VLANs for the transmission of packets.

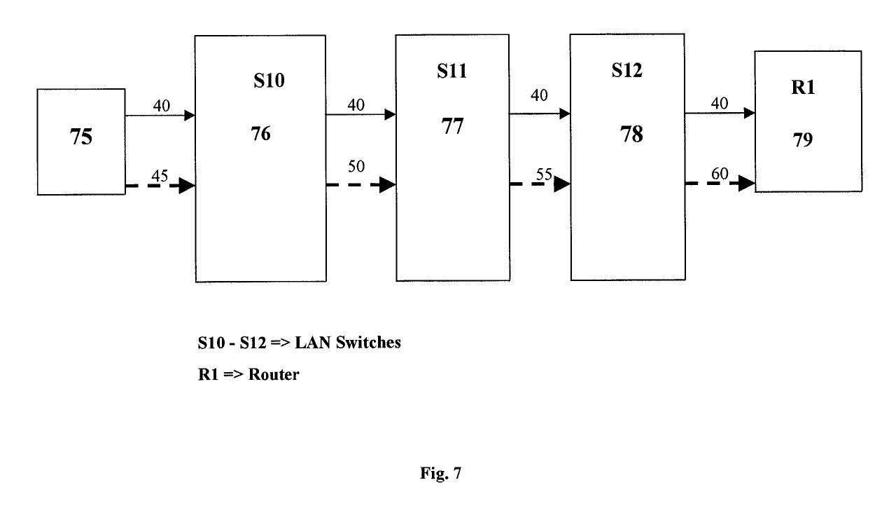

FIG. 7 illustrates the transmission of a packet through an enterprise LAN including a plurality of switches by utilizing one VLAN and also by utilizing two VLANs according to an embodiment of the present invention. For example, VLAN 40 may be utilized throughout the plurality of switches with each switch having information regarding VLAN 40 in its VLAN endsystem table, and VLAN port designation table. Alternatively, endsystem 75 may transmit a packet as a member of VLAN 45 to LAN S10 76, which receives the information on port 4. LAN switch S10 76 may recognize that any packet received on port 4 is part of VLAN 50 and transmit the packet based on its VLAN table information for VLAN 50 to LAN switch S11 77, which receives the information on port 6. LAN switch S11 77 may recognize that any packet received on port 6 is part of VLAN 55 and transmit the packet based on its VLAN table information for VLAN 55 to LAN switch S12 78, which receives the information on port 8. LAN switch S12 78 may recognize that a packet received on port 8 involves VLAN 60 and may transmit the packet based on its VLAN table information for VLAN 60 to Router R1 79.

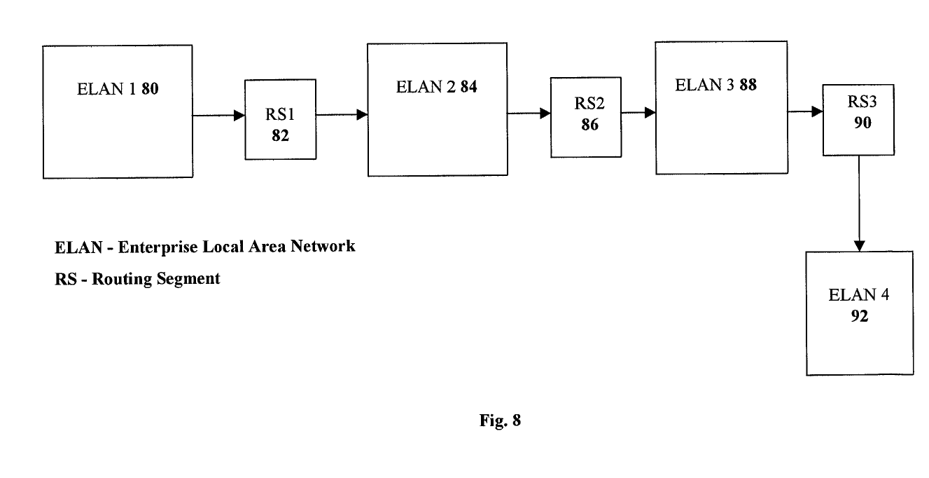

The present invention is not limited to an end-to-end virtual circuit including a source enterprise local area network (LAN), a plurality of routers, and a destination enterprise LAN. The secure virtual circuit may span multiple enterprise LANs connected together by routing segments. FIG. 8 illustrates a virtual circuit with multiple enterprise local area networks connected by multiple routing segments according to an embodiment of the present invention. The end-to-end virtual circuit (EEVC) spans enterprise LAN 1 80, routing segment 1 (RS1) 82, enterprise LAN 2 84, routing segment 2 (RS2) 86, enterprise LAN 3 88, routing segment 3 (RS3) 90, and enterprise LAN 4 92. VLANs are utilized in the first enterprise LAN 80, and the last enterprise LAN 92, to transmit packets as described previously. In each of the routing segments, an MPLS label-switched path (LSP) is created to transmit the packets through the routing segments, as discussed previously. Although the path the packets travel in the intermediate enterprise LANs (ELAN 2 84 and ELAN 3 88) is similar to the packet path in a destination or source enterprise LAN, a description is helpful because the enterprise LANs are now accepting packets of data and also transmitting packets of data.

A VLAN-ID is established to enable communications over an intermediate enterprise LAN. In one embodiment of the invention, the VLAN includes the last router (egress router) on the routing segment preceding the intermediate enterprise LAN, the switch on the intermediate enterprise LAN, and the ingress router on the routing segment succeeding the intermediate enterprise LAN. In one embodiment of the invention, an endsystem or a plurality of endsystems may also be included in the VLAN with the preceding egress router, the LAN switch, and the succeeding ingress router. For example, if users on endsystems that are connected to the LAN switch on this intermediate LAN segment are participating in the application, (such as a conference call), the users may receive the packets. The LAN switch on the intermediate enterprise LAN receives the packet from the egress router of the preceding routing segment, determines the router is part of a VLAN by utilizing its VLAN endsystem, and VLAN port designation tables, and distributes the packet to members of the VLAN utilizing techniques discussed previously. Because one of the members of the VLAN is the ingress router of the succeeding routing segment, the packet/packets are transmitted to the ingress router.

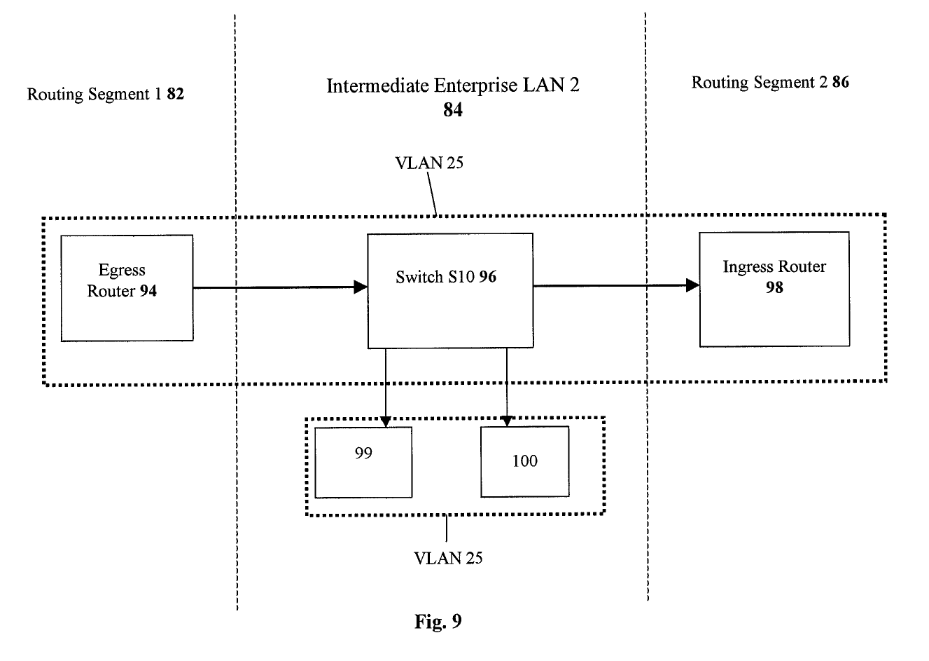

FIG. 9 illustrates an intermediate enterprise local area network's (LAN's) transmission of data packets from a preceding routing segment to a succeeding routing segment according to an embodiment of the invention. FIG. 9 includes an egress router 94 of routing segment RS1 82 (see FIG. 8), a LAN switch S10 96 located in enterprise LAN 2 84, and an ingress router 98 of routing segment RS2 86. VLAN 25 includes egress router 94, LAN switch S10 96, and ingress router 98 as members of the VLAN. The data packet is transmitted from the egress router 94 to the LAN switch S10 96. S10 96 recognizes that router 94 is part of VLAN 25, determines what other devices are associated with VLAN 25, determines what ports are associated with VLAN 25, and transmits the data through these ports. In this embodiment of the present invention, the packet is transmitted out of a switch port connected to ingress router 98 because it is a member of VLAN 25. After receiving the packet, the ingress router 98 starts the creating of the label-switched path in routing segment 2 86.

The present invention involves an end-to-end virtual circuit that spans multiple enterprise LANs and a global network. A transmission is established from a source endsystem to a destination endsystem. The source endsystem is located on an enterprise local area network (LAN). A VLAN-ID, that includes the ingress router of the global network, is established to transport the packet from the source endsystem to the ingress router on the global network. The global network includes MPLS-enabled routers. A label-switched path is established to transport the packets from the ingress router to the egress router in the global network. A second VLAN-ID, that includes the egress router of the global network, is established to transport the packet from the egress router on the global network to the destination endsystem.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes that come within the meaning and range of equivalency of the claims are intended to be embraced therein.

What is claimed is:

1. A method of forwarding data packets from a source endsystem in a first enterprise local area network (LAN) to a destination endsystem in a second enterprise LAN through a plurality of multi-protocol labeling system (MPLS)-aware routers on a global network, comprising:
establishing a first virtual LAN identifier (VLAN-ID) to transport all data packets from the source endsystem to an ingress routing device on the global network;
creating a label-switched path (LSP) through the plurality of MPLS-aware routers to transport all of the data packets from the ingress routing device to an egress routing device on the global network; and
establishing a second VLAN-ID to transport the data packets from the egress routing device to the destination end system in the second enterprise LAN.

2. The method of claim 1, wherein the first and second VLAN-IDs are established by a network administrator.

3. The method of claim 1, wherein the first and second VLAN-IDs are established by a software program.

4. The method of claim 1, wherein the global network is an Internet.

5. The method of claim 1, wherein a third VLAN-ID is used in conjunction with the first VLAN-ID to transport the data packets from the source endsystem to the ingress routing device on the global network.

6. The method of claim 1, wherein a route of the label-switched path is determined by hop-by-hop routing.

7. The method of claim 1, wherein a route of the label-switched path is determined by explicit routing.

8. The method of claim 1, wherein the ingress router is included in the first VLAN-ID.

9. The method of claim 1, wherein the egress router is included in the second VLAN-ID

10. A method of forwarding data packets from a source endsystem in a first enterprise local area network (LAN) to a destination endsystem in a second enterprise LAN through at least one intermediate enterprise LAN and at least two Multi-Protocol Labeling System (MPLS)-aware routing segments, comprising:
establishing a first virtual LAN identifier (VLAN-ID) to transport data packets from the source endsystem to a first MPLS-aware routing device in a first of the at least two MPLS-aware routing segments;
creating a label-switched path (LSP) from the first MPLS-aware routing device through a last MPLS-aware routing device for each routing segment;
establishing a VLAN-ID in each intermediate enterprise LAN to transport data packets from a last router on a preceding routing segment to a first router on a succeeding routing segment; and
establishing a second VLAN-ID in the second enterprise LAN to transport data packets from the last MPLS-aware routing device on a last routing segment to the destination endsystem.

11. The method of claim 10, wherein the first and second VLAN-IDs are created by a software program.

12. The method of claim 10, wherein the first and second VLAN-IDs are created by a network administrator.

13. The method of claim 10, wherein a route of the label-switched path is determined by hop-by-hop routing.

14. The method of claim 10, wherein a route of the label-switched path is determined by explicit routing.

15. The method of claim 10, wherein the global network is an Internet.

16. The method of claim 10, wherein the ingress router is included in the first VLAN-ID.

17. The method of claim 10, wherein the egress router is included in the second VLAN-ID.

18. A virtual end-to-end circuit to transport packets over a first enterprise network, a global network, and a second enterprise network, comprising:
a packet transfer device to initiate transfer of the packets from one end of the virtual end-to-end circuit to another end;
a virtual local area network (VLAN) in the first enterprise network to transport the packets from the packet transfer device through the first enterprise network to an ingress router on the global network;
a label-switched path (LSP) to enable the packets to be transported from the ingress router to an egress router on the global network; and
a second virtual local area network (VLAN) in the second enterprise network to transport the packets from the egress router through the second enterprise network to a destination endsystem.

19. The system of claim 18, wherein the global network is an Internet.

20. The system of claim 18, wherein the packet transfer device is a server.

21. The system of claim 18, wherein the packet transfer device is a computer workstation.

22. The system of claim 18, wherein the VLAN is created at a LAN switch.

23. The system of claim 18, wherein the VLAN is created at an endsystem.

24. A virtual end-to-end circuit to receive a group of packets spanning a first enterprise local area network (LAN), a global network, and a second enterprise LAN, comprising:
a packet receiving device in the second enterprise LAN to accept transfer of the group of packets over the virtual end-to-end circuit;
a packet transmitting device in the first enterprise LAN;
a first virtual local area network (VLAN) to transmit the group of packets securely through the first enterprise LAN to an ingress router on the global network;
a label-switched path in the global network to transmit the group of packets securely from the ingress router to an egress router in the global network; and
a second VLAN to transmit the group of packets securely from the egress router through the second enterprise LAN to the packet receiving device.

25. The system of claim 24, wherein the global network is an Internet.

26. The system of claim 24, wherein the packet receiving device is a server.

27. The system of claim 24, wherein the packet receiving device is a computer workstation.

28. The system of claim 24, wherein the first and second VLANs are created at a LAN switch.

29. The system of claim 24, wherein the first and second VLANs are created at an endsystem.
